(19) United States
(12) Patent Application Publication
(10) Pub. No.: US 2010/0264335 A1
(43) Pub. Date: Oct. 21, 2010

(54) PATTERN WRITING ON A ROTATING SUBSTRATE

(75) Inventors: Philip Clifford Hoyle, Cambridge (GB); Nigel Charles Edward Crosland, Delmar, NY (US); Andrew William McClelland, Cambridge (GB); David Martin Platton King, Newmarket (GB); Ian Laidler, Haddenham (GB); Jason Geraint Seaborne Williams, Cambridge (GB)

Correspondence Address: SUGHRUE MION, PLLC, 2100 PENNSYLVANIA AVENUE, N.W., SUITE 800, WASHINGTON, DC, 20037, US

(73) Assignee: VISTEC LITHOGRAPHY INC., Watervliet, NY (US)

(21) Appl. No.: 12/671,161

(22) PCT Filed: Mar. 26, 2008
(86) PCT No.: PCT/GB2008/001101

§ 371 Date: Jun. 23, 2010

(30) Foreign Application Priority Data
Jul. 31, 2007 (GB) 0714913.1

(51) Int. Cl. H01J 37/30

(52) U.S. Cl. 250/492.3

(57) ABSTRACT

A method of producing an array of islands (12) on concentric tracks (13) on a rotating substrate by selective exposure of an electron-sensitive surface of the substrate to an electron beam comprises directing the beam onto a point (A) on the surface within a zone of action of the beam and deflecting the beam in the sense (31) of substrate rotation to remain on the point until the point (A′) has received an electron dose from the beam. The beam is then redirected onto a further point (B or T) at a spacing from the preceding point (A′) and dosed by the beam in similar manner. The redirection and deflection procedure is repeated for at least one substrate revolution, preferably several revolutions, so that points are dosed along at least one of the tracks (13a), preferably several of the tracks (13a to 13j). The same procedure is then repeated, in conjunction with continuous or periodic linear displacement of the substrate perpendicularly to its axis of rotation to shift the zone of action across the substrate, until points are dosed along all intended tracks on the substrate, the totality of dosed points forming the array of islands.

The present invention relates to pattern writing by an electron beam and has particular reference to a method of producing an array of islands on a substrate, especially a rotating substrate, by selective exposure of an electron-sensitive surface of the substrate to an electron beam.

Writing of finely detailed patterns with features dimensioned in nanometres on substrates by exposure to the electrons of an electron beam is well-established and can be extended to include production of high-density arrays for creation of, inter alia, discrete magnetic storage islands on data storage media, such as hard drive discs of data processing equipment. Writing of patterns of the last-mentioned kind could be carried out by conventional boustrophedon scanning in an electron beam lithography machine with X-Y stage displacement of the substrate. Successive pattern subfields, i.e. small adjoining areas of islands, in a main field would be written by periodic beam deflection with intervening beam blanking and then successive main fields written with the help of stage X or Y displacement. Although it would be possible with this writing procedure to achieve an array of islands on a substrate, it is inconvenient to correlate the island array, which basically has a grid layout, with the circular paths that are required for scanning islands on a discoid substrate intended to rotate, in use, as in a hard drive. The boustrophedon writing procedure, which entails beam deflection along rectilinear paths, would have to be controlled so that the islands when written actually lie on concentric tracks. A particular difficulty is represented by the problem of achieving accurate stitching or mating of the very substantial number of individual subfields making up the totality of the pattern, especially when time-dependent errors due to drift compromise alignment of island rows at X and Y boundaries. This imposes limitations on practicality and economic viability having regard to the substantial number of islands required in such arrays and consequently the amount of time required to complete writing.

Writing on a rotating substrate which can also be linearly displaced represents a more suitable approach and machines of this basic kind exist, albeit for specific purposes. One such machine for producing digital video discs and other data storage discs, such as those readable by blue-violet laser light, has a non-deflectable beam which maintains a constant position and is blanked between exposure positions (islands) and which writes a spiral track of dots intended to be read in the same chronological order as in writing. A spiral track format is incompatible with bit pattern media requiring concentric circles of islands so that the islands can be addressed in freely selectable order by a reader. This island format places very tight constraints on placement accuracy of the islands, both in radial direction and circumferential direction of the substrate disc, and these demands have not yet been satisfactorily met by existing writing procedures and associated pattern writing tools.

It is therefore the principal object of the present invention to provide a method of pattern writing of, in particular, an array of islands on concentric tracks on a substrate by an electron beam in such a manner that a high level of island placement accuracy may be achievable in conjunction with a desired high rate of writing. A further object is the writing of patterns of the stated kind on a rotating substrate so that conventional scanning procedures, such as boustrophedon scanning or vectored scanning with their attendant disadvantages of comparatively slow writing speed and susceptibility to subfield stitching errors where high-density dot arrays are concerned, can be circumvented.

A subsidiary object is creation of a writing method in which use can be made of continuous or substantially continuous substrate motion, i.e. rotation, to accelerate the writing procedure by eliminating at least some stop-and-start aspects of writing and by confining the area of beam action to a relatively small range.

A further subsidiary object is to reduce writing time by elimination, entirely or at least to a substantial extent, of beam blanking during island writing so that, in effect, the beam is almost constantly active with respect to the substrate surface to be patterned.

Another subsidiary object is to increase island placement accuracy by a multiple exposure procedure so that the final position of each island can be determined as an average of several exposures, rather than simply by a single exposure.

Yet another subsidiary object is to enhance accuracy of island writing by superimposing control influences on the beam, especially corrective reorientation of the beam independently of predetermined beam deflections for actual writing of islands, so that corrections for placement errors can be made as and when detected.

A further subsidiary object is creation of a versatile writing procedure capable of producing not only the array of islands, but also, within the array, radially extending linear patterns or other patterns of selectable form.

Other objects and advantages of the invention will be apparent from the following description.

According to the present invention there is provided a method of producing an array of islands on concentric circular tracks on a substrate by selective exposure of an electron-sensitive surface of the substrate to an electron beam, comprising the steps of
rotating the substrate in a given sense about an axis of rotation substantially perpendicular to the electron-sensitive surface thereof,
directing an electron beam onto a point on the electron-sensitive surface of the rotating substrate within a zone of action of the beam on the surface and deflecting the beam in the sense of the substrate rotation to remain on that point until the point has received a predetermined electron dose from the beam,
redirecting the electron beam onto a further point on the electron-sensitive surface of the rotating substrate at a spacing from the preceding point and within the zone of action and deflecting the redirected beam in the sense of the substrate rotation to remain on that further point until the further point has received a predetermined electron dose from the beam,
repeating the step of redirecting the beam and deflecting the redirected beam for at least one revolution of the substrate so that points are dosed along at least one track concentric with the axis of substrate rotation,
further repeating the step of redirecting the beam and deflecting the redirected beam for at least one further revolution so that points are dosed along at least one further track concentric with the axis of substrate rotation, the totality of dosed discrete points on the concentric tracks forming the array of islands, and
displacing the substrate substantially perpendicularly to the axis of substrate rotation to shift the zone of action across the substrate.

Such a method allows high-speed, substantially uninterrupted writing of a high-density island array, in particular by taking advantage of rotational movement and also progressive linear movement of the substrate, rather than stop-and-start reciprocating movement in two orthogonal (X and Y) directions. Substrate rotation can be continuous and at an angular velocity or angular velocities selected to optimally dose the electron-sensitive surface and possibly to optimise speed of writing. Since the substrate undergoes linear displacement in conjunction with rotational movement, the zone of action of the beam, in particular the writing field of the beam writing spot, can be confined to a very small area or path. Beam deflection is then correspondingly easier to manage. The combination of a deflectable beam acting on a rotating and linearly displaceable substrate creates a precondition for writing on concentric circular tracks, as distinct from spiral tracks, and thus allows generation of island arrays with an island disposition optimised for data storage media in the nature of hard drive discs.

The step of rotating the substrate preferably comprises rotating the substrate at substantially constant speed in each revolution, which thereby provides a fixed reference parameter on the basis of which other aspects of the writing procedure can be determined, especially the electron dose per island. Maintenance of a constant rotational speed also simplifies operation of the pattern writing tool employed. However, variation of the substrate rotational speed within a revolution remains possible and variation of the speed of rotation between different regions of the substrate to which the zone of action is shifted may be advantageous to assist maintenance of a consistent pattern density as the array develops radially outwards or inwards.

Similarly, the beam current is preferably maintained at a substantially constant level in each revolution so as to simplify writing procedures and writing tool operation. Maintenance of a constant current level ensures that the islands are exposed to the same electron dose, assuming consistent duration of exposure. It may, however, be advantageous to vary the level of beam current between different regions of the substrate to which the zone of action is shifted, for example in areas which may require modified writing procedures such as initial or final phases of writing, or where different shapes, for example lines, are to be incorporated in the array.

For preference the beam is redirected by jumping to each further point, in particular a snap deflection of the beam at such a velocity that negligible exposure of the substrate electron-sensitive surface along the path traced by the beam during the snap action occurs. This rapid beam redirection is a desirable precondition for the particularly advantageous possibility of carrying out beam redirection without blanking the beam during movement between successive points, i.e. the beam remains constantly active. Blanking effectively equates with switching on and switching off the beam and elimination of this step on each occasion of beam redirection confers a significant reduction in time for writing the array.

The step of displacing the substrate is preferably carried out so that each further track is disposed further from or closer to the axis of substrate rotation than the respective preceding track, which has the result that the displacement is unidirectional and writing takes place in a radially outward or inward direction of the substrate, as a consequence of which the effect of drift is minimised and thus time-dependent error reduced. Writing is progressive over directly adjoining concentric tracks, with the result that the zone of action of the beam represents a moving window in which writing errors can be kept to a minimum. It is, however, equally possible for writing to start in any selected intermediate position and progress in selected directions.

The writing procedure is preferably such that the step of displacing can be carried out continuously, which may provide a useful saving in time by comparison with step-and-settle displacement of the substrate. It is then necessary to correct the beam orientation to compensate for any error in beam position caused by the continuous displacement, which may otherwise tend to generate slightly spirally extending tracks. Alternatively, the step of displacing can be carried out periodically, in which case the step of further repeating can be carried out in each of the intervals between such periodic displacements.

In one procedure for producing the array of islands, i.e. island writing strategy, the step of redirecting the beam and deflecting the redirected beam comprises movement of the beam in a direction counter to the sense of the substrate rotation so that the points dosed in the at least one revolution during the step of repeating lie along a single track concentric with the axis of substrate rotation. In this procedure, all the points are dosed along a single track before movement to another track, which can be by beam redirection, by substrate linear displacement or by a combination of both, for example beam redirection in the course of writing a certain number of tracks followed by substrate displacement.

In a preferred alternative procedure, however, the step of redirecting the beam and deflecting the redirected beam comprises redirecting the beam onto a plurality of further points in succession by movement of the beam initially in a first direction substantially radially of the substrate with respect to the axis of rotation, then in a direction counter to the sense of the substrate rotation, then in a second direction substantially radially of the substrate, but opposite to the first direction, and finally again in a direction counter to the sense of the substrate rotation and deflecting the beam after each said movement thereof to provide each of the further points with the predetermined electron dose so that the points dosed in the at least one revolution during the step of repeating lie along a plurality of tracks concentric with the axis of substrate rotation. In this procedure, writing is carried out over a number of tracks at the same time by diverting the beam radially to one or more new tracks, subsequently counter to substrate rotation, then radially back to or towards the original track and finally once again counter to substrate rotation. The radial movement can range simply between the original track and a single adjacent track, in which case the beam is redirected to a single further point in each of the first and second radial directions, or can encompass a number of tracks, in which case the beam is redirected to a series of further points in each of the first and second radial directions. The speed of beam redirection by comparison with the substrate rotational speed is such that multiple-track writing is possible within certain limits, for example two to twenty adjoining tracks. The first radial direction is preferably a direction away from and the second direction a direction towards the axis of rotation of the substrate, so that writing progresses in radially outward direction on the substrate. Writing is equally possible in the opposite direction or, in a variant procedure, in both directions, for example—and assuming an appropriate starting point—by shifting the beam a certain distance in the first radial direction, then a greater distance in the second (opposite) radial direction and then by the same certain distance in the first radial direction to take the beam back to the track at which it started.

With regard to electron dosage of points the simplest procedure is to impart to each point the level of dose required to form an island in a single exposure to the beam electrons. However, it has proved advantageous for the predetermined dose imparted to each point in the steps of directing/deflecting and redirecting/deflecting to be a fraction of the dose needed to form an island. Accordingly, the step of repeating is preferably carried out for a plurality of revolutions of the substrate so that each point along the at least one track receives the predetermined dose in each of the revolutions. The number of revolutions in that plurality can then be determined so that each point along the at least one track receives a multiple of the dose until a given total dosage has been attained, namely the dosage required to form an island. The dosage of each point is thus gradually built up to provide the given total dosage. The specific advantages resulting from this approach are that the reduced exposure time on the occasion of each visit to a point allows an optimally high substrate rotational speed and any error in placement of a point, i.e. the beam writing spot position, in the course of a single revolution may be reduced or eliminated by subsequent exposures of the same point with—on average—correct placement, assuming the error source is merely transient or is corrected in the course of the time taken to build up the given total dosage or, at least, is not consistently harmonic with substrate rotation. The position of each point is, in effect, an average of multiple exposures. The number of revolutions for the purpose of multiple exposure is preferably determined in dependence on the speed of substrate rotation and the level of beam current and can typically be, for example, two to ten.

The redirection of the beam is preferably carried out so that the pitch of the points along the tracks remains substantially the same, the pitch radially of the tracks preferably being similarly equidistant so that the array of islands considered in any radial strip across the tracks is generally grid-shaped in a manner optimum for storage and reading requirements in a data storage disc. By way of example, the points can have a pitch of 10 to 100 nanometres along the tracks and a pitch of 10 to 3000 nanometres radially of the substrate. With respect to island density, the steps of redirecting, repeating and displacing can be carried out to produce at least half a million concentric tracks of the points on the electron-sensitive surface of the substrate. A lesser number of tracks is, of course, possible. The number may be governed by substrate size and, if serving as a master for a data storage medium or conceivably as the medium itself, by intended storage or memory capacity.

The islands formed by the points can be, for example, substantially round or substantially elliptical. Other shapes can be realised by various methods, such as beam shaping apertures. It is also possible to define each point by a plurality of contiguous dots successively exposed by the electron beam, for which purpose the dots can be exposed in succession by deflecting the beam along a predetermined dot path corresponding with a given island shape and size.

If the substrate is to serve as a master for a data storage medium, for example a discoid medium with data storage islands selectably addressible by a scanning head with a requirement to identify islands in terms of track position in both radial and circumferential directions, it is desirable or necessary to incorporate in the island array a number of servo sectors containing, for example, patterns able to generate location signals. Such patterns are typically formed by radial lines of selectable form and disposition. In order to produce servo sectors of this kind or related pattern features the method of the present invention can include the step, interpolated into each of the steps of repeating and further repeating and carried out at least once per revolution of the substrate, of forming a pattern extending radially of the substrate with respect to the substrate axis of rotation. For preference the interpolated step is interpolated a plurality of times in each substrate revolution at spaced-apart radii of the substrate so that a desired number—as many as several hundred—servo sectors can be formed around the substrate. The spaced-apart radii and thus the servo sectors are preferably equidistant in the rotational direction of the substrate. Such a pattern can be, for example, a series of spaced-apart and radially extending lineal traces, which are preferably formed by solid lines, although formation by lines of discrete dots is equally possible. Depending on pattern requirements, at least some of the lineal traces in the series are each composed of a plurality of discrete length sections, which can be separated by, for example, gaps of selectable lengths and in selectable positions. At least some of the lineal traces in the series can be of different lengths and/or spacings.

The lineal traces can be written in various ways, one possible procedure entailing formation of each lineal trace in the series by directing the beam onto a plurality of points, in succession, directly adjoining one another radially of the substrate with respect to the axis of rotation and deflecting the beam after each redirection to remain on the respective point until it has received a predetermined electron dose from the beam. Gaps in the lineal traces can be formed simply by causing the beam to bypass selected points or by blanking the beams at selected points.

A further significant feature of a method exemplifying the invention can be represented by a superordinate step of defining on the electron-sensitive surface of the substrate an active field representing the zone of action of the beam in which the steps involving directing, redirecting and deflecting the beam are performed, a correction field including and surrounding the active field and a registration field including and surrounding the correction field, carrying out corrective adjustment of the beam-to-substrate relationship within the correction field and carrying out initial registration of the substrate position relative to the beam within the registration field. Whilst it is conventional practice in pattern-writing procedures to fracture patterns into main fields and then the pattern features in the main fields into subfields in which actual writing by beam scanning is performed one subfield at a time, the proposed superordinate step in a method exemplifying the present invention employs three fields of which the two larger fields are used for, respectively, registration of the beam relative to the substrate and correction of beam position. The corrective adjustments can be performed continuously, particularly with a view to providing correction for errors attributable to at least one of eccentricity, vibration, temperature change, fluctuations in voltage or current and substrate displacement substantially perpendicularly to the axis of substrate rotation. Correction for error in substrate linear displacement may be of particular importance in writing procedures in which, for example, the displacement is continuous so that error is introduced for which compensatory beam reorientation is essential.

In a practical example of the method the substrate can be fixedly mounted on a rotatable and linearly displaceable support for producing the rotation of the substrate about the axis and the displacement of the substrate substantially perpendicularly to the axis. Such a support can comprise a rotary stage rotatably mounted on a linearly displaceable stage. The electron-sensitive surface of the substrate is preferably provided by an electron-sensitive coating on a body of the substrate.

The invention also embraces a substrate provided on an electron-sensitive surface thereof with an array of islands produced by a method exemplifying the invention, such a substrate being, for example, a master processible for mass production of products, such as hard-drive discs for data storage, each bearing the array of islands. The substrate could itself be such a hard-drive disc, in which the islands, after being metallised, can be individually magnetically influenced for the data storage.

The invention further provides, in yet another aspect, an electron beam pattern writing machine for producing an array of islands on concentric circular tracks on a substrate by selective exposure of an electron-sensitive surface of the substrate to an electron beam, comprising generating means for generating an electron beam, a rotatable and linearly displaceable support for holding the substrate with the electron-sensitive surface thereof disposed so as to be acted on by the beam, the stage being rotatable to rotate the held substrate in a given sense about an axis substantially perpendicular to the electron-sensitive surface thereof and being linearly displaceable to displace the held substrate substantially perpendicularly to the axis of rotation, and control means for directing the generated electron beam onto a point on the electron-sensitive surface of the rotating substrate within a zone of action of the beam on the substrate, deflecting the beam in the sense of the substrate rotation to remain on that point until the point has received a predetermined electron dose from the beam, redirecting the electron beam onto a further point on the electron-sensitive surface of the rotating substrate at a spacing from the preceding point and within the zone of action, deflecting the redirected beam in the sense of the substrate rotation to remain on that further point until the further point has received a predetermined electron dose from the beam, repeating the step of redirecting the beam and deflecting the redirected beam for at least one revolution of the substrate so that points are dosed along at least one track concentric with the axis of substrate rotation, further repeating the step of redirecting the beam and deflecting the redirected beam for at least one further revolution so that points are dosed along at least one further track concentric with the axis of substrate rotation, the totality of dosed discrete points on the concentric tracks forming the array of islands, and displacing the substrate substantially perpendicularly to the axis of substrate rotation to shift the zone of action across the substrate. The control means preferably comprises at least one beam deflecting system and a stage drive both controllable by software commands.

Methods exemplifying the present invention will now be more particularly described with reference to the accompanying drawings, in which:

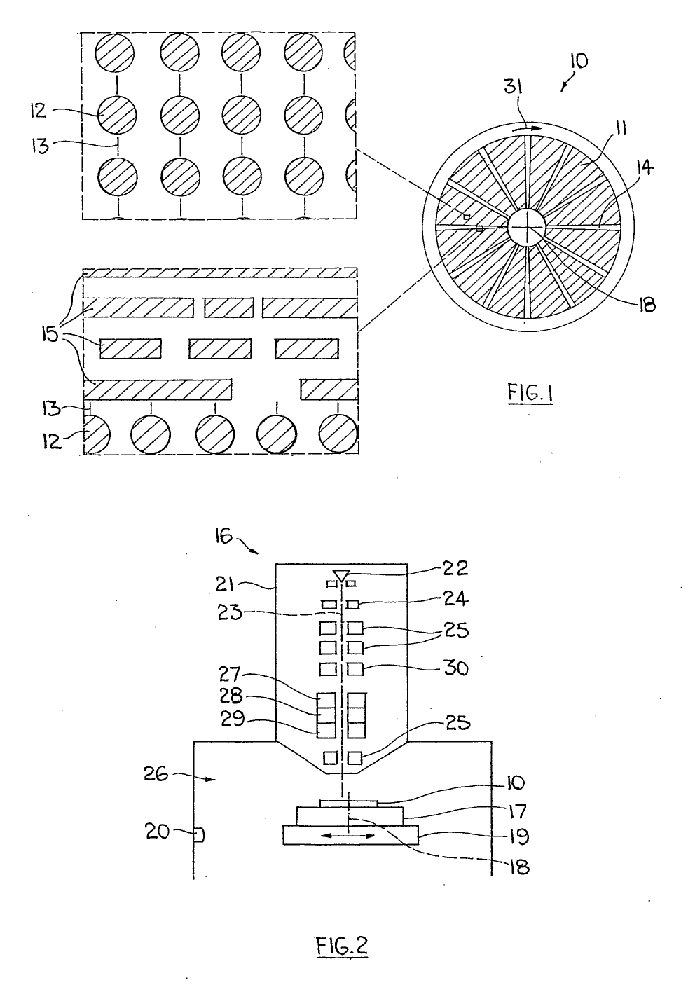

FIG. 1 is a schematic view of a substrate bearing a pattern composed of an array of islands and periodically intervening servo sectors able to be produced by a method exemplifying the invention, in association with two detail views to enlarged scale respectively illustrating details of the island array and details of a servo sector;

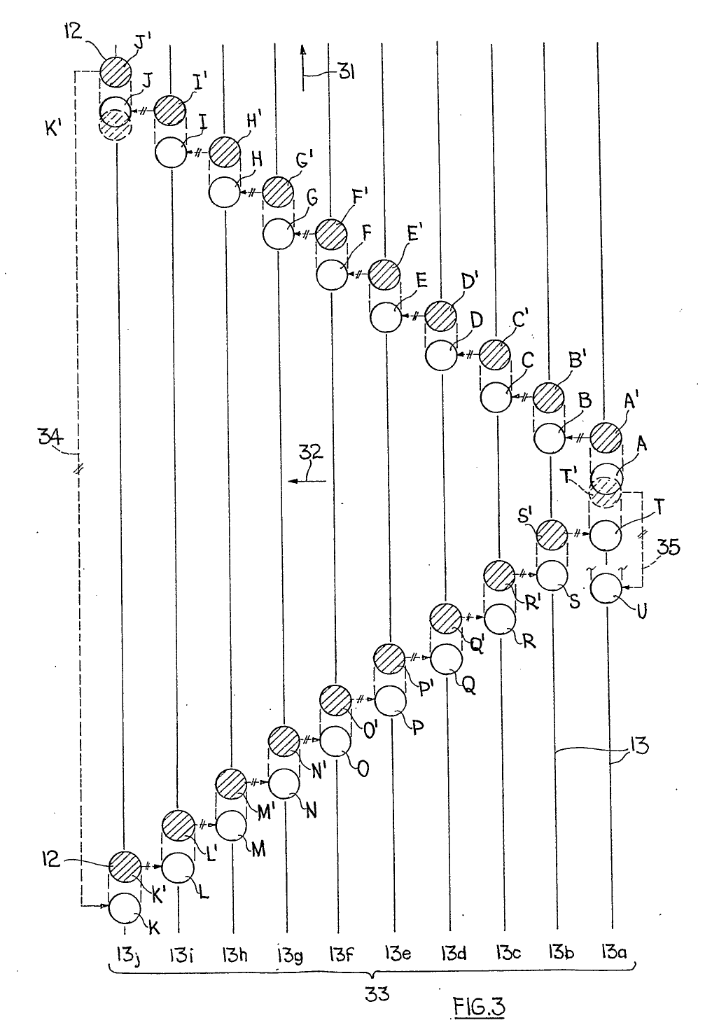

FIG. 2 is a schematic elevation of an electron beam lithography machine equipped for performance of a method exemplifying the invention;

FIG. 3 is a diagram showing a writing strategy for writing the array of islands in a method exemplifying the invention;

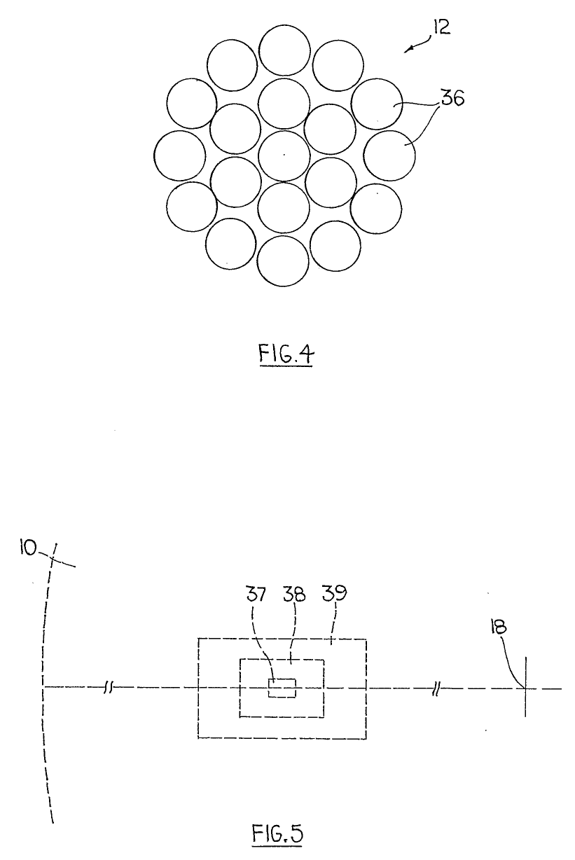

FIG. 4 is a diagram of a dot arrangement making up an island in one version of such a method; and

FIG. 5 is a diagram of electron beam deflection fields used in writing the array of islands.

Referring now to the drawings there is shown in FIG. 1 a highly schematic illustration of a substrate 10 having an electron-sensitive surface on which an array 11 of islands 12 is to be produced on concentric circular tracks 13 by selective exposure of the surface, while the substrate is rotating, to an electron beam, in particular exposure of discrete points on the surface. The array of islands on the substrate 10 is depicted simply as a hatched area. The substrate is, by way of example, a circular silicon wafer with an electron-sensitive surface formed by coating a face of the wafer with a suitable resist, for example polymethylmethacrylate (PMMA). The wafer can be square or any other desired shape. In the course of writing the islands 12 a writing spot, which is focussed on the surface, of the electron beam changes the chemical structure of PMMA in the sense of rendering it more soluble to a developer. A written pattern, i.e. the array 11 of islands 12, can be developed by immersion of the substrate in an organic solvent. Thereafter the pattern in the resist is transferred to a metallic or other coating material. The finished substrate can serve as, for example, a master for mass-production of hard-drive discs, such as used in a hard drive of a computer or other data-processing equipment, by an optical or other method acting more rapidly than electron beam writing, in which only one island at a time can be formed.

FIG. 1 also includes two magnified detail views to very substantially increased scale; in fact, the scale relationship is such that the rectangular areas shown on the substrate 10 as the locations of the detail views would be detectable only microscopically. The upper detail view shows that the islands 12 run serially along the circular tracks 13 concentric with the centre of the circular substrate, starting at a radial distance of about 5 or 6 millimetres and ending at a radial distance of 40 to 50 millimetres from the centre. Typically 1.5 million or more tracks 13 of islands 12 are formed on the substrate 10, the tracks having a radial pitch of, for example, 25 nanometres and each track containing islands at a pitch again of, for example, 25 nanometres. The number of islands per track obviously increases with increasing distance from substrate centre. The totality of tracks is notionally divided into concentric regions (not illustrated) in radially outward direction of the substrate, for example 20 regions, each region consisting of, for example, 50,000 to 75,000 tracks. Since the island pitch is to remain substantially the same over the entire substrate 10, the concentric regions define rotational speed boundaries at which substrate rotational speed is increased (in radially outward direction) to remove any variation in pitch that may otherwise occur with constant rotational speed. Island density can thus be maintained at a substantially constant level. Within each concentric region, groups of adjacent tracks are treated as bands on which islands are produced at the same time during each substrate revolution as explained in more detail below in connection with the writing strategy for producing the array of islands.

The islands 12 themselves, as apparent from the upper detail view of FIG. 1, are preferably round or elliptical, although ideally they could be square to maximise magnetisable material area. The round islands can have a diameter of, for example, 15 nanometres. If elliptical, the ellipse has its major axis oriented radially of the substrate and an axis ratio of, for example, 1:1.5. Each island can be formed by a single exposure element (dot) or by several contiguous elements as explained further below

As evident from FIG. 1 and the lower detail view the totality of island tracks 13 on the substrate 10 is interrupted by equidistantly spaced sectorial spokes, termed servo sectors 14, extending across all tracks 13, in which lineal traces rather than islands are formed. Only a small number of the sectors 14 is shown in FIG. 1 and in the present example it is envisaged that about 200 to 300 such sectors will be present on the substrate. The lineal traces, here in the form of lines 15, in each servo sector 14 can be of different lengths and variously have interruptions or breaks at selected points to form unique identifiers of the tracks 13. Some of the lines 15 in each sector 14 can also be arranged at different spacings from one another. The arrangement and form of lines shown in the lower detail view of FIG. 1 simply exemplify some possibilities. Instead of lines as such, rows of discrete dots simulating lines can provide the lineal traces. In use, the servo sectors 14 allow the tracks 13 to be individually identified radially of the substrate 10 and individual parts of each track to be identified in the angular or circumferential sense of the substrate. For identification purposes the servo sectors 14 serve to generate, when scanned, location signals and also synchronisation signals.

Production of the array 11 of islands 12 and also the servo sector line arrangements is carried out on an electron beam lithography machine 16 for writing patterns, machines of this kind being well-known and therefore not described in detail. However, the machine required for carrying out methods exemplifying the present invention will have features specific to writing the pattern described above, i.e. the island array 11 and servo sectors 14. Thus, the machine 16 incorporates a rotary stage 17 on which the substrate 10 is fixedly mounted so as to be rotatable about an axis 18 coinciding with its centre. The rotary stage 17 is in turn carried by a linearly displaceable stage 19 so that the mounted substrate can be displaced perpendicularly to the axis 18, i.e. diametrally, either continuously or, if appropriate to the writing procedure employed, periodically. The linear displacement is monitored by a usual laser interferometry system 20 precisely detecting instantaneous stage position and supplying feedback to a displacement control system (not shown) for a stage drive. The machine 16 incorporates an electron beam column 21 with a thermal field emission electron gun 22 for generation of an electron beam which propagates along an axis 23 of the column—thus also the beam axis—and which is shaped by an aperture 24 or several apertures and focused by a series of lenses 25 in the column to produce a writing spot on the electron-sensitive surface of the substrate 10. The substrate 10 and stages 17 and 19 that carry it are located in a vacuum chamber 26 providing a vacuum environment essential to the electron propagation. The column 21 also includes deflecting means for deflecting the beam and thus the writing spot so that the writing spot can selectively act on the substrate electron-sensitive surface in a confined zone of action in accordance with the particular pattern to be written, in this case the described array 11 of islands 12 on concentric tracks 13 interrupted by equidistantly spaced servo sectors 14. The zone of action is defined by, for example, a selected range of deflection of the beam in one or more directions and can be of any shape or even merely linear, depending on the capabilities of the deflecting means and the pattern-writing requirements. The deflecting means in this machine comprises, in departure from conventional arrangements, three deflecting systems 27, 28 and 29 with respectively different rates of action. The fastest deflecting system 27, for example an octopole or dodecapole electrostatic system with a bandwidth of 500 to 2000 megahertz, is primarily for deflecting the beam for the actual pattern writing, whilst the slowest system 29, for example an electromagnetic system with a bandwidth of up to about 100 kilohertz, is employed for initial beam registration relative to the substrate 10 and other tasks not requiring fast response. The intermediate-speed deflecting system 28, which can again be an electromagnetic system, but in this instance with a bandwidth of about 50 megahertz, is primarily used for position error correction. A more detailed explanation of the uses of the three systems within respective fields of action is given further below. Each of the electromagnetic deflecting systems 28 and 29 comprises two mutually independent orthogonal deflectors respectively aligned on two mutually perpendicular diameters intersecting at the beam axis 23 and each deflector comprises two coils which are positioned on the respective diameter on either side of the path of beam propagation and the supplied power of which can be varied between the coils to produce magnetic fields of different strength inducing movement of the beam in the direction of the field of greatest strength. With appropriate control of the coils of the two orthogonal deflectors of a deflecting system the beam can be constrained in any direction. The beam deflection by the fastest deflecting system 27 is under the control of machine operating software effectively causing direct translation of a given pattern, i.e. the island array 11 and servo sectors 14, into differential voltage supply to plates of the system. The column also includes a beam blanking system 30 for blanking the beam, i.e. removing the writing spot from the substrate surface, during beam deflection and stage linear displacement. However, in marked contrast to conventional pattern-writing procedures, in the writing procedures described further below the blanking facility is employed selectively and can be entirely withheld from action during basic writing of at least the island array 11.

One strategy for pattern writing on the substrate 10 to produce the array 11 of islands 12 on the equidistantly spaced concentric circular tracks 13 is illustrated in FIG. 3, in connection with which it should be noted that the sequence of actions shown in the figure is superimposed on the substrate while rotating and optionally while linearly moving, as a consequence of which the sequence is merely representational and does not give a precise depiction of the relative physical disposition of the islands 13 or their individual orientation. In addition, the scale is such that the curvature of the circular tracks 13 is not detectable and the illustrated lengths of the tracks appear simply as straight lines. The substrate 10 is fixed on the rotary stage 17 and the stage set into continuous rotation about the axis 18 at a constant speed in a given rotational sense, for example clockwise as viewed from above the substrate and as indicated by the arrow 31. The rotational speed is matched to the exposure requirements for formation of the islands 12, as explained further below. Although the rotational speed of the substrate 10 carried by the rotary stage 17 remains constant in each revolution of the substrate at least for writing the islands 12, the speed can be changed from revolution to revolution if this should be desirable or essential in connection with aspects of producing the array 11 of islands. The speed is, however, changed from one of the afore-mentioned concentric regions to the next, thus as the size of the array 11 increases. In addition, the rotational speed in each revolution could conceivably differ between the periods in which the islands 12 are produced and the periods in which the lines 15 of the servo sectors 14 are produced, depending on the respective demands on time for the two forms of writing. Preferably, however, a constant speed is maintained and any potentially time-consuming increases in pattern density are dealt with by influencing the beam with respect to position, deflection and/or current.

The substrate 10 and the beam are correlated in position so that the zone of action of the beam deflection is positioned for movement generally along a given radius of the substrate. The radially outward direction of the substrate, with respect to the track lengths shown in FIG. 3, is indicated by arrow 32. The zone of action of the beam remains substantially constant in its dimensions, but varies in position on the substrate 10 as a result of diametral displacement of the substrate by way of the linearly displaceable stage 19, as described further below. The zone of action of the beam thus constitutes a radially moving writing window. The beam current is set to a constant value, but, as in the case of the substrate rotational speed, can be varied from revolution to revolution, from region to region radially of the substrate or within a revolution if the pattern writing demands make a greater or lesser electron dosage desirable or necessary in different phases of writing.

In the writing procedure or strategy shown in FIG. 3 use is made of the available rapidity of beam deflection allowed by the machine capabilities, i.e. speed of movement of the writing spot on the substrate surface, to write islands on a band 33 of adjacent tracks 13—in this case ten—within such a short period of time that progressive writing of the pattern can be achieved during continuous rotation of the substrate. Writing speed or throughput is thereby substantially increased and may be limited only by the resist sensitivity and the available electron beam current. This capability of island writing on multiple tracks or a band, whilst permitted by the speed of writing spot movement, is also influenced by such parameters as, in particular, the speed of substrate rotation, the level of beam current and the beam dosage rate; the electron dose intended for each exposure element or dot dictates, in conjunction with beam current, the duration of each exposure and consequently the time consumed in writing. The number of tracks 13 forming a band 33 can thus be determined in dependence on the mentioned parameters and on the dimensions of the zone of action of the beam (selected deflection range) and may be greater or lesser in number than the ten which are shown, merely by way of example, in FIG. 3.

For writing the islands 12 on the tracks 13 of a band 33 the beam and substrate are, for example, so positioned relative to one another, by movement of the linearly displaceable stage 19, that the axis 23 of the undeflected beam approximately intersects the centre of the band 33 with the respect to the radial direction 32 of the substrate. The zone of action of the beam is such as to cover at least the full radial width of the band and a distance appropriately larger than the island pitch along the tracks. At the start of the writing procedure the beam is then directed so that the writing spot thereof is positioned on a point A on a track 13a which, with respect to the substrate radial outward direction denoted by the arrow 32, is closest to the centre of the substrate. The successive radially outlying tracks 13 making up the band 33 are denoted 13b to 13j. The described writing procedure entails a sequence of steps progressing initially from the radially innermost track 13a of the band 33 to the radially outermost track 13j of that band and subsequently from the track 13j back to the track 13a. It is, however, entirely possible to commence at the track 13j and progress to the track 13a before returning to the track 13j. It is equally possible to commence at any one of the intermediate tracks, for example 13e, and progress in radially outward or inward direction to the respective extremity of the band, then to the other extremity and finally back to the starting track. The procedure evident from FIG. 3 represents a simple procedure clarifying the principle of a strategy for multiple-track or band writing of islands, but constitutes merely an example.

After positioning of the beam writing spot on the point A, which is represented by a vacant circle, on the track 13a and with the substrate rotating at constant speed in the sense indicated by the arrow 31 the beam is deflected in the sense of the substrate rotation so that the writing spot of the beam remains on the point A until that point has been exposed to a predetermined electron dose. The path of beam deflection is indicated by parallel dotted lines either side of the line of the track 13a and the dosed point, which is represented by a hatched circle, is denoted by A′. The beam is then redirected, by an abrupt deflection or jumping as indicated by a radially outwardly oriented dashed-line arrow and without blanking of the beam, to a further point B located radially outwardly of the dosed point A′ and on the adjacent track 13b in radially outward direction. The redirection of the beam is by an amount corresponding with the pitch of the points in radial direction, for example 25 nanometres. Deflection of the beam in the sense of substrate rotation so that the writing spot remains on the point B until it has received the predetermined electron dose then follows, the dosed point similarly being denoted by B′. The same steps of beam redirection, by jumping, to a new, radially outwardly disposed point and beam deflection to follow the point during substrate rotation are then repeated with progression through points C to J (vacant circles) respectively located on tracks 13c to 13j so as to form dosed points C′ to J′ (hatched circles). Since the tracks are equidistant, the beam redirection for radially outward movement of the writing spot takes place over the same distance in each instance, as signified by oblique equality lines superimposed on the radially oriented dashed-line arrows between the dosed and undosed points.

After exposure of point J on track 13j to the beam electrons so as to form dosed point J′, the beam is redirected, by abrupt deflection or jumping and without blanking, in a sense opposite to the sense of substrate rotation as indicated by the directional dashed line 34 to the left of and parallel to the track 13j so as to position the beam writing spot on a point K still lying on the track 13j, but spaced behind the last dosed point J′ with respect to the sense 31 of substrate rotation. The redirection is by the same amount as that carried out in movement of the writing spot between adjacent points in the series A′ to J, as signified by the same oblique equality lines superimposed on the directional dashed line 34. For the purposes of clearer illustration of the succeeding sequence of writing, however, the directional dashed line 34 is of very much greater length than the dashed-line arrows between the individual points in the series A′ to J. The redirection of the beam in the sense opposite to the substrate rotation is through a distance equal to the island pitch spacing in the substrate radially outward direction 32, i.e. 25 nanometres in this case, because ultimately the island pitch radially of the substrate is to be the same as that along the tracks 13, so that the islands 12 considered in a group of, for example, 10×10 are located on a regular grid (discounting the imperceptible track curvature in such a small area). If, however, the islands 12 are to be located on an irregular grid with a radial pitch differing from the pitch along the track, the beam redirection in the sense 34 counter to substrate rotation is correspondingly smaller or larger.

After redirection of the beam to the point K on the track 13j a series of points is dosed in similar manner to the points A′ to J′, but with progression in a radially inward direction of the substrate 10 over the same tracks in reverse sequence to return to the track 13a. Thus, initially the beam is deflected in the sense 31 of the substrate rotation so that the writing spot of the beam remains on the point K until that point has been exposed to the predetermined electron dose, the path of beam deflection again being indicated by parallel dotted lines. The dosed point, again represented by a hatched circle, is denoted by K′. The actual position of the dosed point K′ in relation to the immediately preceding dosed point J′ is shown in dotted lines at the top of the track 13j, i.e. just behind the undosed point J with respect to the sense 31 of substrate rotation. Thereafter, the unblanked beam is redirected, by jumping as indicated by a radially inwardly oriented dashed-line arrow, to a further point L located radially inwardly of the dosed point K′ and on the adjacent track 13i in radially inward direction. The beam is once more deflected in the sense 31 of substrate rotation so that the writing spot remains on the point L until it has received the predetermined electron dose and forms the dosed point L′ which actually lies just behind the undosed point I. The steps of beam redirection to new, radially inwardly disposed points and beam deflection to follow the points during substrate rotation are then repeated with progression through points M to T (vacant circles) respectively located on tracks 13h to 13a so as to form dosed points M′ to T′ (hatched circles).

After writing the island 12 to be represented by the dosed point T′ (shown in dotted lines so as not to obscure the undosed point A) the described cycle is repeated, commencing with redirection of the beam in the sense opposite to that of substrate rotation as indicated by the directional dashed line 35 to the right of and parallel to the track 13a so as to position the writing spot on a further point U located on the track 13a, but spaced behind the dosed point T′ by the same pitch distance (25 nanometres) as applicable to the previously mentioned redirections of the beam. This equality of distance is again signified by superimposed equality lines, although for reasons of illustration the directional dashed line 35 is once more of greater length than the dashed-line arrows indicating the radially oriented beam redirection steps. Repetition of the described writing cycle has the result that the dosed point (not shown) obtained by deflecting the beam to remain on the point U during substrate rotation will ultimately lie just behind the undosed point T.

The part of the writing procedure described in the preceding paragraphs with reference to FIG. 3 is carried out until completion of a full revolution of the substrate, at which time dosed points will have been formed along the tracks 13a to 13j of the band 33 entirely around the substrate 10. Whilst it is possible for the predetermined electron dose imparted to each point during that single revolution to be sufficient to form an island 12 in the sense of readiness for development by a suitable solvent it is preferred to impart only a proportion, for example a half to a tenth, of the dose ultimately required for successful development. In order to achieve a total dose sufficient for development, the entire writing procedure on the tracks 13a to 13j of the band 33 is repeated over a corresponding number of substrate revolutions, i.e. two to ten in this example. The dose at each of the points is thus progressively built up until it has attained the intended level. Such a multiple exposure of each point over a plurality of substrate revolutions confers specific advantages with respect to writing speed and writing accuracy. In addition, elimination of blanking on each occasion of redirection removes the hysteresis associated with activation and deactivation of the machine beam blanking system 30, thus allowing faster writing, and generally simplifies machine control and operation as well as eliminating charging-related position drift induced by blanking. The individual dose level is so low and the beam deflection (jumping) for redirection so quick that ‘smearing’ by the unblanked beam does not occur. Writing accuracy is improved because multiple writing of each point has the important consequence of achieving an ‘averaged’ position, thus reducing undesired displacement of the point from an ideal or a predetermined co-ordinate position. In effect, any such displacement on a single occasion or even a few occasions of exposure due to error in beam writing spot positioning (attributable to machine vibration, thermally induced shift and other sources of noise) is negated or largely negated by subsequent exposures at the ideal position and/or at a position displaced in opposite sense, assuming interim correction of the error by the continuous correction procedures mentioned further below or, at least, non-recurrence of the identical error if transient in nature.

In order to fully utilise the mentioned advantages resulting from multiple dosage or exposure of points, especially the position averaging, and removal of beam blanking phases, it is desirable to optimise the fundamental machine operating parameters governing writing of the islands 12. For this purpose, following determination of an appropriate dose D per island for the substrate resist in question and a suitable beam current I_{B}, a maximum island formation rate f_{f} can be determined as f_{f}=I_{B}/D. If each island is exposed n times with 1/n of the determined dose D the island exposure rate or island visit rate fₑ is then given by fₑ=n(I_{B}/D). Since the beam is not blanked, the angular velocity ω of the rotary stage 17, thus substrate 10, must be matched to the period of exposure, namely 1/fₑ=p_{θ}/rω, wherein p_{θ} is the island pitch along the track and r the radial distance between substrate centre and instantaneous position of the beam writing spot. This then has to be adapted to take into account the requirement for multi-track island exposure, i.e. exposure of islands 12 across a band of m tracks before redirection of the beam by p_{θ}, so that the island exposure period in this circumstance becomes 1/fₑ=p_{θ}/mrω. It then becomes possible to determine the required angular velocity ω of the rotary stage 17 or substrate 10 as a function of the radius r by the equation: ω=fₑp_{θ}/mr=n(I_{B}/D)·p_{θ}/mr. In practice, since the angular velocity ω is kept constant within a zone, the island pitch p_{θ} along the track will vary linearly with radial distance r.

If, by way of example, D is 1 femtoCoulomb and I_{B} is 10 nanoamps then the full island formation rate f_{f} is 10 megahertz, but assuming dosing over ten substrate revolutions the island exposure rate fₑ becomes 100 megahertz. In the case of an island pitch p_{θ} of 25 nanometres along the track and if only one track at a time were to be written, the stage angular velocity ω at a radius of 25 millimetres would be 100 radians per second or approximately 16 revolutions per second, whereas for the example of writing a band of ten tracks at a time (m=10) the stage angular velocity becomes 1.6 revolutions per second. The dwell time of the beam writing spot on a point when imparting 1/n of the required total dose D is only 10 nanoseconds in the case of an exposure rate of 100 megahertz. The area of resist between islands should generally receive less than one tenth of the dose on each occasion and, since the beam is not blanked when jumping between points, in the example of a 25 nanometre track pitch this implies jumping between points in about 1 nanosecond.

It is accordingly possible to select the track number m so that the rotary stage 17 or substrate 10 rotates at an optimal angular velocity, for example for minimum non-repeatable run-out or so that the averaging effect is optimised. The maximum value of m is determined by the maximum deflection range of the fast-action deflecting system 27 carrying out the island writing and the track pitch, i.e. island pitch radially of the substrate.

The effect of averaging by exposing an island n times with 1/n of the determined dose D can lead to an improvement in overall placement accuracy by approximately 1/√n. This assumes that placement errors are small by comparison with the island diameter and that the error due to noise of whatever origin is normally distributed. If, however, the error in placement is non-Gaussian due to domination by a small number of noise frequencies the effect may be reduced, particularly if the noise frequency is a harmonic of the substrate revolution frequency. The noise will then be ‘sampled’ at the same point in each cycle in the mean and the averaging achieved by multiple dosage of each island may then not compensate for placement error. This may be able to be addressed by avoiding certain rotary stage or substrate rotational frequencies. In addition, in the case of close proximity to harmonics the effectiveness of the averaging may be reduced, but the bandwidth over which this reduced effectiveness occurs can be reduced by increasing the number of averages, i.e. the island exposure rate.

The above-described determination of writing parameters assumed a nominally constant beam current I_{B}, although in practice, with writing of the island array 11 occupying hours or even days, a slow variation in current may occur due to drift in the thermal field emission gun 22 of the machine column 21 or in electromagnets present in the lenses and beam blanking and deflecting systems. This variation can be detected by, for example, measuring the extractor current, i.e. the current between the tip of the gun 22 and an associated extraction electrode, the anode current, i.e. the current between the extra-high tension accelerating voltage and ground, and the current impinging on the beam-defining aperture 24 in the column. The island exposure rate and the rotary stage angular velocity can then be adjusted, so as to maintain a constant dose, in dependence on the detected variation in beam current.

After exposure of all the selected points along a plurality of tracks 13 forming a band 33 to the electron beam, the procedure is repeated for a further band of tracks radially adjoining the band of tracks just processed, in this example adjoining in the radially outward direction of the substrate, and composed of the same number of tracks. For this purpose the substrate 10 is diametrally displaced by the linearly movable stage 19 through a step corresponding with the width of the band to shift the zone of action of the beam in the sense of, for example, realignment of the axis 23 of the undeflected beam with the centre of the further band. Continuous or substantially continuous stage diametral displacement is equally possible and in practice may be preferred, subject to superimposition of a constant correction of the beam writing spot position by the correction measures described further below. Points along the tracks of the further band are then written, i.e. exposed to the beam electrons, in the same manner as described for the tracks 13a to 13j of the preceding band 33. Subsequently, the island array 11 is written on further radially outwardly adjoining bands of tracks, with—unless stage diametral displacement is continuous—diametral displacement of the substrate 10 on each transition to a succeeding band, until completion of the number of bands, for example, 5,000 to 7,500, constituting one of the concentric regions. At this point writing is continued in the next such region at increased substrate rotational speed to eliminate or minimise change in pitch of the exposed points along the tracks, i.e. circumferential pitch, due to increasing radial spacing of the tracks from the substrate centre. Such a change in pitch does, in fact, occur to some extent within a region—where substrate rotational speed is constant—as writing progresses in radially outward direction. Writing is continued by the described procedures until the entire area of the substrate electron-sensitive surface intended to be occupied by the island array 11 is filled with points disposed on the predetermined grid and subjected to electron dosage thereby to form the islands 12 capable of development and transfer to a metal coating.

As indicated above, multiple track writing of the array 11 of islands 12 may also be carried out by a procedure in which diametral displacement of the substrate 10 is performed continuously or substantially continuously to constantly shift the zone of action of the beam in, for example, radially outward direction. In this procedure, writing action is again undertaken on all the tracks, for example ten, of a band at the same time, but the tracks constituting the band constantly change by advancing the writing action towards a new radially outermost track while writing of the track currently occupying the radially innermost location continues. The writing action over the tracks making up the band progresses in such a way that the dosage levels of the points on the tracks as a result of the above-described multiple dosage procedure are, at any one time, graduated across the tracks of the band, in particular diminish from track to track in radially outward direction. Thus, for example, when the points on the radially innermost track have each been dosed ten times as a consequence of repeated dosing over ten revolutions of the substrate 10, the points on the next track in radially outward direction will each have been dosed nine times, those on the track after that eight times, and so forth. This can be achieved by employing a modification of the strategy shown in FIG. 3. In this case, for example, initially the writing of points is undertaken solely along a first track, here the radially innermost track, by redirecting the beam each time in a sense counter to the substrate rotation to move the writing spot to a further point on the same track at the conclusion of exposure of the preceding point. After one revolution of the substrate the beam redirection procedure is amended to additionally write points along the immediately adjacent track, i.e. the beam is redirected radially outwardly to a point on that adjacent track, then counter to the sense of substrate rotation to a further point lying on the same track, but behind the point just exposed, then radially inwardly to a further point on the radially innermost track and then in a sense counter to the substrate rotation to the following point on the radially innermost track. The two points on the radially innermost track will have already been dosed once in the first revolution of the substrate and thus are now dosed for a second time, whereas the two points on the adjacent track will be dosed for the first time. This sequence of writing is continued for a further revolution, at the conclusion of which all the points along the radially innermost track will have been dosed twice and all the points along the adjacent track will have been dosed once.

At the commencement of the next revolution of the substrate the beam redirection radially outwardly is extended to yet another track and at the commencement of each revolution thereafter to a further track until writing action is taking place on all ten tracks making up a band. Since each point on each track is also to be dosed ten times, at the conclusion of the tenth revolution of the substrate the points along the radially innermost track (the first to be written) of the band will each have been dosed ten times and those along the radially outermost or tenth track (the last to be written) of the band will each have been dosed once. At the commencement of the next revolution of the substrate, writing of the points on the first track is terminated and the beam redirection procedure is amended to exclude that track and to encompass a new radially outermost or eleventh track. At the commencement of the revolution following that, writing on the second track is concluded and the beam redirection procedure thus omits that track and is advanced to take in a twelfth track. The procedure thus continues on the basis of terminating, at the commencement of each revolution, writing at the track which is then radially innermost and commencing writing on a new radially outermost track. Writing across the substrate is thus progressive with stepping of one track at a time. In such a procedure it is possible to move the linearly displaceable stage 19 continuously, even during writing of points along the first ten tracks, and to carry out constant correction, by way of the correction measures mentioned further below, for departures of the beam writing spot from ideal co-ordinate positions. The velocity ν_{L} of the linearly displaceable stage 19 is dependent on the angular velocity ω of the rotary stage 17 (thus of the substrate 10) and assuming a displacement by one track pitch pᵣ per revolution can be resolved as ν_{L}=pᵣω/2π. The resulting velocity may be very small, for example 400 nanometres per second if ω=100 radians per second.

The explanation of the multiple track writing procedure with track-by-track incrementation of the band across the substrate assumed formation of the band from ten tracks and dosage of each point ten times by way of repeated dosing over ten substrate revolutions. These numbers are merely arbitrary: a greater or lesser number of tracks can be regarded as making up a band, which represents the number of tracks along which points are written simultaneously, and the number of times each point is dosed can be varied according to requirements, particularly with reference to preferred levels of beam current, preferred substrate rotational speed and superordinate considerations such as writing throughput and writing accuracy.

Although, as described above, it is preferred to produce the island array 11 by pattern writing on multiple tracks 13 in each substrate revolution, it is equally possible to carry out writing on a single track per revolution. This under-utilises the speed capabilities of the fast-acting beam deflection system 27, but the loss may be able to be offset at least in part by increasing substrate rotational speed. The writing procedure carried out on a single track per revolution would simply require redirection of the beam on each occasion in a sense counter to substrate rotation to move the writing spot to a further point on the same track after exposure of the preceding point. Redirection in a radial sense would be carried out only after a full substrate revolution if each point is exposed only once or a predetermined number of revolutions if each point is exposed several times to achieve a total dose. Stage diametral displacement can be carried out continuously, with superimposed correction of the beam writing spot position, or in steps after, for example, writing a number of tracks.

The individual points exposed to electrons in the afore-described examples of writing strategies were depicted as circular in shape and ostensibly each formed by a single exposure element or dot. The shape can equally well be elliptical or rectangular, to mention the two most obvious alternatives. In practice, particularly for generating non-circular shapes, it may be advantageous to define the shape of each point (island) by a plurality of dots 36, such as shown in FIG. 4 for a circular shape composed of 19 dots. It will be readily apparent that with this method a different arrangement of dots can provide a rectangular or other desired shape without resorting to use of a shaped beam. The dots 36 are exposed in a predetermined sequence by rapid beam deflection, preferably a sequence allowing beam movement from the first to last dot in the least time. The movement of the beam to sequentially expose the dots making up each point is carried out continuously and repetitively (which may include reversals of scan direction) during the deflection of the beam to follow the point during the substrate rotation, i.e. deflection of the beam between the dots making up the point is superimposed on the beam deflection to follow the point as a whole. In the case of the configuration illustrated in FIG. 4 for a point in an array with a regular grid having a 25 nanometre pitch, the point has, by way of example, a diameter of 15 nanometres and each dot a diameter of 3 nanometres. The clock governing dosage rate has to operate at 19 times the rate for exposure of a point forming an island 12, so that in the case of, for example, an island exposure rate of 100 megahertz the dot exposure rate would be 1.9 gigahertz.

If writing of the islands is to be carried out with formation of each point of the desired size (diameter or major/minor axes) and shape by a single dot, use can be made for this purpose of an intentionally defocused beam providing a writing spot of the intended size and shape. Assuming a beam focussing system with negligible spherical aberration, all incoming electrons of the beam can be focussed to a single point on the beam optical axis. Half the angle α of the beam-shaping aperture in the machine column forms a contribution to writing spot size, which is defined as full width half maximum (FWHM) and which increases linearly with distance Δz from the Gaussian image plane coincident with the substrate surface, thus: spot size contribution Δd_{FWHM}=2αΔz.

Accordingly, in the case of, for example, half angle α=4.5 milliradians the spot size contribution is Δd=9 nanometres per micron. Since the spot size in the image plane is approximately 5 nanometres, the spot size in this example increases almost linearly with defocus distance when Δz is greater than 1 micron.

In practice, however, the spherical aberration in lens systems employing electromagnetic lenses is not negligible, with the result that electrons are focussed to different points along the optical axis depending on the radial position of each incoming ray. Electrons further from the axis receive stronger focussing and the spherical aberration is therefore positive. As a result of this aberration, the full width half maximum still varies more or less linearly with the offset from the image plane, but the shape of the writing spot depends on the direction of the offset. If the offset is closer to a final one of the lenses 25 of the lens system than the image plane, the edge acuity of the spot is similar to that in the image plane. Further from the final lens, the spot has shallower sides. Consequently, good spot edge acuity can be achieved if the final lens is intentionally under-focussed. In the case of, for example, a final lens in the form of a compound lens with a fast coil for fine focussing and a double-quadruple stigmator, the coil can be controlled to intentionally increase beam size while maintaining a spot edge acuity consistent with the degree of contrast required for writing the islands 12.

An elliptical shape of the writing spot can be imposed on the beam simply by use of an elliptical final aperture, so that the aperture half angle is different in orthogonal planes. However, in the case of a compound final lens as described in the preceding paragraph greater flexibility can be achieved by use of the stigmator, which focuses the beam differently in orthogonal directions. With the stigmator the difference in focus between orthogonal axes and the orientation of those axes is controllable during the island exposure time.

As already noted in connection with explanation of the substrate pattern depicted in FIG. 1 the array 11 of islands 12 is periodically interrupted by the equidistant servo sectors 14, which must be produced in the course of writing the islands by interrupting the island writing procedure, in particular by interpolating at the required equidistant radial positions a changed writing procedure specific to the line arrangements present in the servo sectors. For this purpose the machine software control switches at appropriate intervals to different pattern generation which influences the beam deflection, and if necessary other writing parameters such as substrate rotational speed, beam current and beam deflection rate or exposure element clock, to write contiguous dots forming the lines 15 or possibly discrete dots defining lineal traces equivalent in function to solid lines, i.e. scannable with the same result. During servo sector writing the substrate rotational speed and the beam current are generally maintained at constant values, but either or both may be increased relative to the values applicable to island writing to accommodate the greater exposure element density in a servo sector. Alternatively, if constant values are maintained and a lag or lead in the beam position on the substrate (in relation to the position optimised for writing of the islands) arises and increases as writing of a servo sector progresses, a correction can be imposed on the beam deflection by the intermediate speed deflecting system 28 to remove the lag or lead.

In one possible procedure for writing the servo sector lines 15, the beam can be directed, as in the case of writing the islands 12, onto a selected point—in this case a point intended to form one end of a line—and deflected in the sense of substrate rotation so that the writing spot follows the point and imparts thereto a predetermined electron dose. Thereafter, the beam can be redirected, for example radially outwardly, to a contiguous point and the beam similarly deflected to follow that point and impart the same electron dose. The procedure is repeated on a radial path across the band of tracks 13 on which islands 12 are, but for the interruption to produce a servo sector 14, then being written so as to complete a radially oriented line formed by contiguous exposed points. The beam can then be redirected in a sense counter to that of the substrate rotation to a point disposed at a spacing behind the last dosed point, i.e. that forming the other end of the line just written. Deflection of the beam to cause the writing spot to remain on the new point during substrate rotation and impart an electron dose will then initiate formation of a second radial line circumferentially spaced from the first line. The beam redirection and deflection procedure is repeated in analogous manner in radially inward direction of the substrate until the second line is complete, after which the beam is again redirected oppositely to the substrate rotation to a position marking the start of a third circumferentially spaced radial line. That and further lines, the spacings of which can be the same in some instances and different in other instances, can be written in the same manner until the servo sector line arrangement has been written its entirety.

In order to interrupt lines 15 to produce gaps of differing length, number and/or position in the lines thereby to impart unique character to each line, for example as shown in the lower detail view in FIG. 1, it is only necessary for the beam redirection radially outwardly and inwardly to bypass, under the control of the pattern generator, one or more contiguous points at a selected location in the line and/or at the beginning or end of the line. The bypassed points will thus form an interruption or interruptions in the continuity of the line or a line of reduced length. Bypassing of points is carried out selectably in accordance with the intended length, number and location of the gap or gaps in each line in the particular servo sector 14 being written. As an alternative to bypassing points and in order to maintain constant pitches of beam deflection in the radial redirection steps, the beam can simply be blanked during deflection to follow selected points on tracks so that an electron dose is withheld from each of these points.

Writing of the islands 12 and the servo sector lines 15 is carried out, as already indicated, over a defined radial path on the substrate and the substrate 10 is continuously or periodically diametrally displaced so that the zone of action of the beam is confined to a particular area, into and through which different parts of the rotating substrate are moved. This zone constitutes, with respect to a notional definition of fields around the intersection of the undeflected beam axis with the substrate as shown in FIG. 5, an active or writing field 37 for directing/redirecting and deflecting the beam to enable placement of the writing spot at ideal co-ordinate positions, defining a shape to be written at each such position and following the stage rotation to write the shape at that position by exposure to the necessary electron dose. Where required, these tasks also include placing, defining and exposing a combination of exposure elements or dots making up a shape such as illustrated in FIG. 4, thus effectively the function of a pattern generator at a basic level. The fastest-acting system 27 of the three afore-described deflecting systems is therefore associated with the active field 37. The active field 37 is incorporated in and surrounded by a larger correction field 38 in which correction is carried out of beam-to-substrate positional errors due to unpredictable sources such as vibration, temperature, eccentricity, etc., and predictable sources such continuous stage linear displacement, as well as adjustment to accommodate pattern density variations and variable positioning of the linearly displaceable stage after stepped displacement. The tasks in the correction field 38 are assigned to the intermediate speed deflecting system 28, which has a slower beam deflection capability than the fast system 27 associated with the active field 37, since only relatively small movements or changes in position of the beam writing spot are needed by comparison with writing of and jumping between points. The correction field 38 in turn is incorporated in and surrounded by a suitably larger registration field 39 for initial beam registration relative to the substrate 10, compensation for slow-changing or large position errors, for example in the linearly displaceable stage position, calibration of the deflecting systems 27 and 28 associated with the other fields 37 and 38, and, if required for pattern accuracy assessment, scanning electron microscope imaging of pattern areas. The registration field 39 is accordingly associated with the slowest system 29 of the three beam deflecting systems. Within the correction field 38 constant monitoring is carried out for positional errors and corrective action is undertaken continuously, whereas action in the registration field 39 is undertaken only at the time of initial setting up of the substrate 10 for pattern writing or whenever the other mentioned special tasks or adjustments arise. The active field 37 is determined to be suitably larger in width, radially of the substrate 10, than a band 33 of tracks (FIG. 3) and in a typical example is approximately 1 to 2 microns square. The correction field 38, by contrast, is approximately 20 microns square and the registration field 39 approximately 200 to 500 microns square.

A method exemplifying the invention as described above may permit economic and high-speed production of an array of islands, with high placement accuracy, on a substrate which can serve as a master for production of a data storage disc or could itself function as such a disc. Pattern transfer of the array can be carried out to create individual islands of metallic or other material.

1-52. (canceled)

53. A method of producing an array of islands on concentric circular tracks on a substrate by selective exposure of an electron-sensitive surface of the substrate to an electron beam, comprising the steps of
rotating the substrate in a given sense about an axis of rotation substantially perpendicular to the electron-sensitive surface thereof,
directing an electron beam onto a point on the electron-sensitive surface of the rotating substrate within a zone of action of the beam on the surface and deflecting the beam in the sense of the substrate rotation to remain on that point until the point has received a predetermined electron dose from the beam,
redirecting the electron beam onto a further point on the electron-sensitive surface of the rotating substrate at a spacing from the preceding point and within the zone of action and deflecting the redirected beam in the sense of the substrate rotation to remain on that further point until the further point has received a predetermined electron dose from the beam,
repeating the step of redirecting the beam and deflecting the redirected beam for at least one revolution of the substrate so that points are dosed along at least one track concentric with the axis of substrate rotation,
further repeating the step of redirecting the beam and deflecting the redirected beam for at least one further revolution so that points are dosed along at least one further track concentric with the axis of substrate rotation, the totality of dosed discrete points on the concentric tracks forming the array of islands, and
displacing the substrate substantially perpendicularly to the axis of substrate rotation to shift the zone of action across the substrate.

54. A method as claimed in claim 53, wherein the step of rotating comprises rotating the substrate at substantially constant speed in each revolution.

55. A method as claimed in claim 53, comprising the step of varying the speed of substrate rotation between different regions of the substrate to which the zone of action is shifted.

56. A method as claimed in claim 53, comprising the step of maintaining the beam current at a substantially constant level in each revolution.

57. A method as claimed in claim 53, comprising the step of varying the level of the beam current between different regions of the substrate to which the zone of action is shifted.

58. A method as claimed in claim 53, wherein the beam is redirected by jumping the beam to each further point.

59. A method as claimed in claim 53, wherein the redirection of the beam is carried out without blanking the beam during movement between successive points.

60. A method as claimed in claim 53, wherein the step of displacing is carried out so that each further track is disposed further from the axis of substrate rotation than the respective preceding track.

61. A method as claimed in claim 53, wherein the step of displacing is carried out so that each further track is disposed closer to the axis of substrate rotation than the respective preceding track.

62. A method as claimed in claim 53, wherein the step of displacing is carried out continuously and the beam orientation is corrected to compensate for any error in beam position caused by the continuous displacement.

63. A method as claimed in claim 53, wherein the step of displacing is carried out periodically and the step of further repeating is carried out in each of the intervals between such periodic displacements.

64. A method as claimed in claim 53, wherein the step of redirecting the beam and deflecting the redirected beam comprises movement of the beam in a direction counter to the sense of the substrate rotation so that the points dosed in the at least one revolution during the step of repeating lie along a single track concentric with the axis of substrate rotation.

65. A method as claimed in claim 53, wherein the step of redirecting the beam and deflecting the redirected beam comprises redirecting the beam onto a plurality of further points in succession by movement of the beam initially in a first direction substantially radially of the substrate with respect to the axis of rotation, then in a direction counter to the sense of the substrate rotation, then in a second direction substantially radially of the substrate, but opposite to the first direction, and finally again in a direction counter to the sense of the substrate rotation and deflecting the beam after each said movement thereof to provide each of the further points with the predetermined electron dose so that the points dosed in the at least one revolution during the step of repeating lie along a plurality of tracks concentric with the axis of substrate rotation.

66. A method as claimed in claim 65, wherein in the step of redirecting the beam and deflecting the beam the beam is redirected to a single further point in each of said first and second directions.

67. A method as claimed in claim 65, wherein in the step of redirecting the beam and deflecting the beam the beam is redirected to a series of further points in each of said first and second directions.

68. A method as claimed in claim 53, wherein the first direction is a direction away from and the second direction a direction towards the axis of substrate rotation.

69. A method as claimed in claim 53, wherein the step of repeating is carried out for a plurality of revolutions of the substrate so that each point along the at least one track receives the predetermined dose in each of the revolutions.

70. A method as claimed in claim 69, wherein the number of revolutions in the plurality thereof is determined so that each point along the at least one track receives a multiple of the dose until attaining a given total dosage, the given total dosage being the dosage required to form an island.

71. A method as claimed in claim 70, wherein the number of revolutions is determined in dependence on the speed of rotation of the substrate and the level of the beam current.

72. A method as claimed in claim 53, wherein the redirection of the beam is carried out so that the pitch of the points along the tracks remains substantially the same.

73. A method as claimed in claim 53, wherein the array of islands in the array have substantially equidistant spacings in at least one of a direction along the tracks and a direction radially of the tracks.

74. A method as claimed in claim 53, wherein the points have a pitch of 10 to 100 nanometres along the tracks.

75. A method as claimed in claim 53, wherein the tracks have a pitch of 10 to 3000 nanometres radially of the substrate.

76. A method as claimed in claim 53, wherein the islands formed by the points are substantially round.

77. A method as claimed in claim 53, wherein each point is defined by a plurality of contiguous dots successively exposed by the electron beam.

78. A method as claimed in claim 53, comprising the step, interpolated into each of the steps of repeating and further repeating and carried out at least once per revolution of the substrate, of forming a pattern extending radially of the substrate with respect to the substrate axis of rotation.

79. A method as claimed in claim 78, wherein the interpolated step is interpolated a plurality of times in each substrate revolution at spaced-apart radii of the substrate.

80. A method as claimed in claim 78, wherein the radially extending pattern comprises a series of spaced-apart and radially extending lineal traces.

81. A method as claimed in claim 80, wherein the lineal traces are selected from the group of solid lines, lines of discrete dots and lines each composed of a plurality of discrete length sections.

82. A method as claimed in claim 80, wherein each of the lineal traces in the series is formed by directing the beam onto a plurality of points, in succession, directly adjoining one another radially of the substrate with respect to the axis of rotation and deflecting the beam after each redirection to remain on the respective point until it has received a predetermined electron dose from the beam.

83. A method as claimed in claim 82, wherein gaps are produced in the lineal traces by one of causing the beam to bypass selected points when forming the lineal traces and of blanking the beam at selected points when forming the lineal traces.

84. A method as claimed in claim 53, comprising a superordinate step of defining on the electron-sensitive surface of the substrate an active field representing the zone of action of the beam in which the steps involving directing, redirecting and deflecting the beam are performed, a correction field including and surrounding the active field and a registration field including and surrounding the correction field, carrying out corrective adjustment of the beam-to-substrate relationship within the correction field and carrying out initial registration of the substrate position relative to the beam within the registration field.

85. A method as claimed in claim 84, wherein the corrective adjustments are carried out to provide correction for errors attributable to at least one of eccentricity, vibration, temperature change, fluctuations in voltage or current and substrate displacement substantially perpendicularly to the axis of substrate rotation.

86. A method as claimed in claim 53, comprising the step of fixedly mounting the substrate on a rotatable and linearly displaceable support for producing the rotation of the substrate about the axis and the displacement of the substrate substantially perpendicularly to the axis.

87. A substrate provided on an electron-sensitive surface thereof with an array of islands produced by a method as claimed in claim 53.

88. A substrate as claimed in claim 87, wherein the substrate is a master processible for mass production of products each bearing the array of islands.

89. A substrate as claimed in claim 86, wherein the products are hard-drive discs for data storage.

90. An electron beam pattern writing machine for producing an array of islands on concentric circular tracks on a substrate by selective exposure of an electron-sensitive surface of the substrate to an electron beam, comprising generating means for generating an electron beam, a rotatable and linearly displaceable support for holding the substrate with the electron-sensitive surface thereof disposed so as to be acted on by the beam, the stage being rotatable to rotate the held substrate in a given sense about an axis substantially perpendicular to the electron-sensitive surface thereof and being linearly displaceable to displace the held substrate substantially perpendicularly to the axis of rotation, and control means for directing the generated electron beam onto a point on the electron-sensitive surface of the rotating substrate within a zone of action of the beam on the substrate, deflecting the beam in the sense of the substrate rotation to remain on that point until the point has received a predetermined electron dose from the beam, redirecting the electron beam onto a further point on the electron-sensitive surface of the rotating substrate at a spacing from the preceding point and within the zone of action, deflecting the redirected beam in the sense of the substrate rotation to remain on that further point until the further point has received a predetermined electron dose from the beam, repeating the step of redirecting the beam and deflecting the redirected beam for at least one revolution of the substrate so that points are dosed along at least one track concentric with the axis of substrate rotation, further repeating the step of redirecting the beam and deflecting the redirected beam for at least one further revolution so that points are dosed along at least one further track concentric with the axis of substrate rotation, the totality of dosed discrete points on the concentric tracks forming the array of islands, and displacing the substrate substantially perpendicularly to the axis of substrate rotation to shift the zone of action across the substrate.
